(19) United States
(12) Patent Application Publication
(10) Pub. No.: US 2014/0292353 A1
(43) Pub. Date: Oct. 2, 2014

(54) LINE IMPEDANCE STABILIZATION NETWORK

(71) Applicants: Hon Hai Precision Industry Co., Ltd., New Taipei (TW); Hong Fu Jin Precision Industry (ShenZhen) Co., Ltd., Shenzhen (CN)

(72) Inventor: YONG-SHENG YANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/962,185

(22) Filed: Aug. 8, 2013

(30) Foreign Application Priority Data
Apr. 2, 2013 (CN) 2013101127645

(51) Int. Cl. G01R 31/00

(52) U.S. Cl. CPC G01R 31/001
USPC 324/613

(57) ABSTRACT

A line impedance stabilization network (LISN) able to withstand high currents includes a power port for connecting to a power supply, an equipment under test (EUT) connection port for connecting to an EUT, and a first inductor connected between the power port and the EUT connection port. The coil includes a first end, an opposite second end, a coiled wire connected between the first end and the second end, and a first and a second resistor. The wire includes a plurality of coils, and the first and second resistors bridge between the starting coil (in each direction) of the coil of wire and two inboard coils of the coil of wire.

### REFERENCES TO RELATED APPLICATIONS

This application is a continuation in part of U.S. patent application Ser. No. 13/921,214, entitled, “LINE IMPEDANCE STABILIZATION NETWORK,” and filed on Jun. 19, 2013.

### BACKGROUND

1. Technical Field

The present disclosure relates to electromagnetic interference (EMI) test technology, and more particularly to a line impedance stabilization network (LISN).

2. Description of Related Art

A line impedance stabilization network (LISN) is peripheral equipment which is used in an EMI test process. Generally, the LISN is connected between an electric supply and equipment under test (EUT) and EMI test equipment. The EMI test equipment can obtain accurate EMI data of the EUT via the LISN. The LISN usually includes inductors, and coils of the inductor are usually made from copper wire and a plastic cover covering the copper wire. However, because the inductors cannot conduct a large current, reliability of the LISN may be reduced.

Therefore, what is needed is to provide a means that can overcome the above-described limitations.

### BRIEF DESCRIPTION OF THE DRAWINGS

The components in the drawings are not necessarily drawn to scale, the emphasis instead placed upon clearly illustrating the principles of at least one embodiment. In the drawings, like reference numerals designate corresponding parts throughout the various views.

FIG. 1 is a circuit diagram of an LISN according to an embodiment of the present disclosure.

FIG. 2 is an isometric view of a first inductor of the LISN of FIG. 1.

FIG. 3 is a cross-sectional view of a wire of the first inductor of FIG. 2.

### DETAILED DESCRIPTION

Reference will be made to the drawings to describe certain exemplary embodiments of the present disclosure.

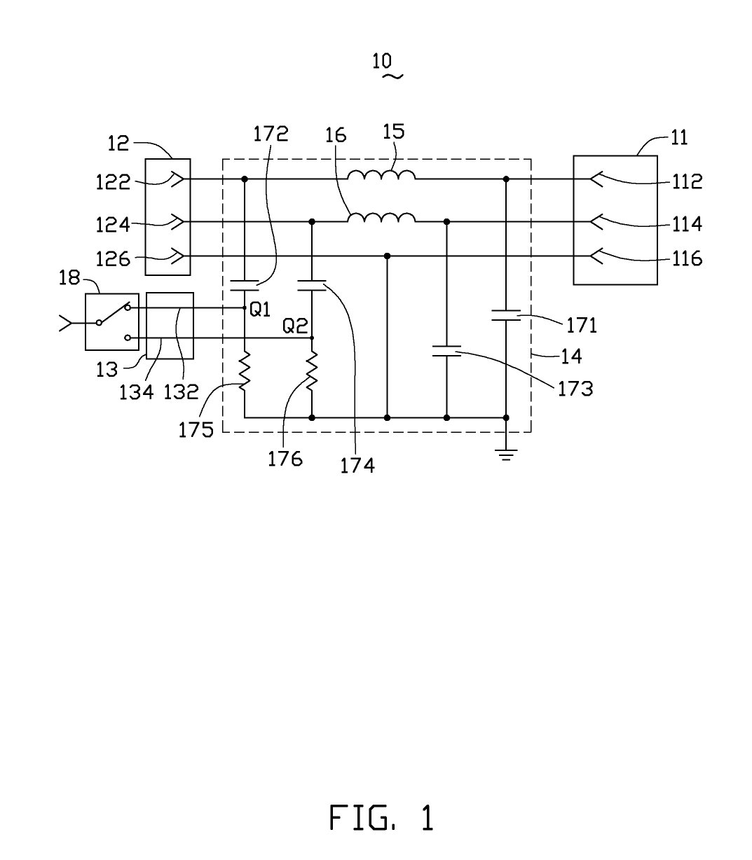

FIG. 1 shows a line impedance stabilization network (LISN) 10 of the embodiment. The LISN 10 includes a power port 11, an EUT connection port 12, an EMI output port 13, and a main circuit 14 connecting the power port 11, the EUT connection port 12, and the EMI output port 13. The power port 11 is configured to connect to an external power supply (such as a commercial power source with 220 volts). The EUT connection port 12 is configured to connect to an EUT. The EMI output port 13 is configured to connect to EMI test equipment, such that the EMI test equipment can measure the EMI data of the EUT via the LISN 10.

The power port 11 includes a first terminal 112 for connecting to a zero line of the power supply, a second terminal 114 for connecting to a voltage line of the power supply, and a grounded terminal 116 for connecting to a ground line of the power supply. The EUT connection port 12 includes a first terminal 133 for connecting to a zero terminal of the EUT, a second terminal 124 for connecting to a voltage terminal of the EUT, and a grounded terminal 126 for connecting to a ground terminal of the EUT. The EMI output port 13 includes a first output terminal 132 and a second output terminal 134. The first output terminal 132 and the second output terminal 134 are all N-type ports. The LISN 10 further includes a switch 18, to switch between the first output terminal 132 or the second output terminal 134 according to user's selection.

The main circuit 14 includes a first inductor 15, a second inductor 16, a first capacitor 171, a second capacitor 172, a third capacitor 173, a fourth capacitor 175, a first grounded resistor 175, and a second grounded resistor 176. The first inductor 15 is connected between the first terminal 112 of the power port 11 and the first terminal 122 of the EUT connection port 12. The second inductor 16 is connected between the second terminal 114 of the power port 11 and the second terminal 124 of the EUT connection port 12.

The first inductor 15 includes a first end 150 connected the first terminal 112 of the power port 11 and an opposite second end 151 connected to the first terminal 122 of the EUT connection port 12. The second inductor 16 includes a first end 160 connected to the second terminal 114 of the power port 11 and an opposite second end 161 connected to the second terminal 124 of the EUT connection port 12. The first capacitor 171 is connected between the first end 150 of the first inductor 15 and ground. An end of the second capacitor 172 is connected to the second end 151 of the first inductor 15, and the other end of the second capacitor 172 is grounded via the first grounded resistor 175. The third capacitor 173 is connected between the first end 160 of the second inductor 16 and ground. An end of the fourth capacitor 174 is connected to the second end 161 of the second inductor 16, and the other end of the fourth capacitor 174 is grounded via the second grounded resistor 176.

The EMI output port 13 includes a first output terminal 132 and a second output terminal 134. The first output terminal 132 is connected to a node Q1 between the second capacitor 172 and the first grounded resistor 175, and the second output terminal 134 is connected to a node Q2 between the fourth capacitor 174 and the second grounded resistor 176.

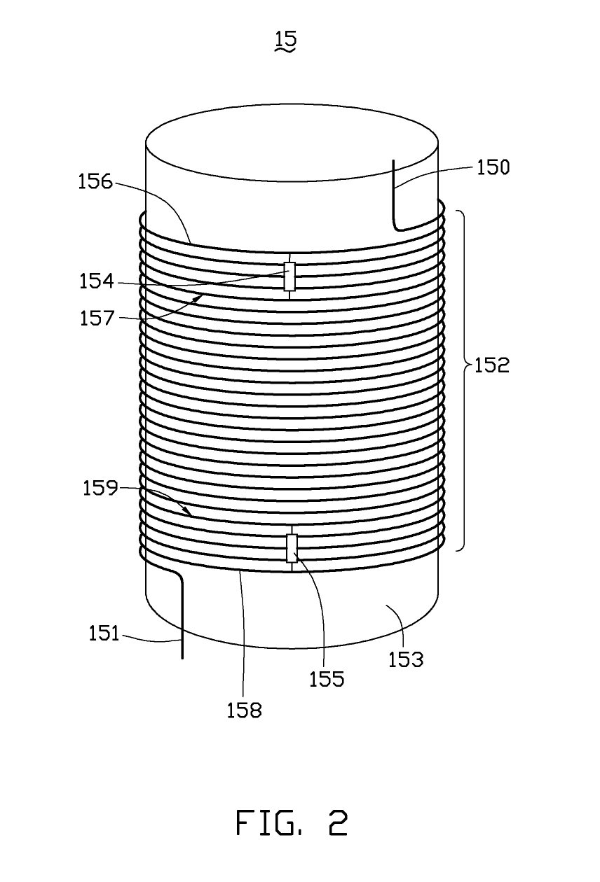

FIG. 2 shows that the first inductor 15 further includes a coil holder 153, a coil of wire 152 connected between the first end 150 and second end 151, a first resistor 154, and a second resistor 155. The second inductor 16 may have the same structure as the first inductor 15. The coil of wire 152 is wrapped around the coil holder 153 helically. Each of the first resistor 154 and the second resistor 155 is connected between two different coils of the coil of wire 152. In one embodiment, the number of coils includes a first coil 156 connected the first end 150 and a last coil 158 connected the second end 151. The first resistor 154 is connected between the first coil 156 and a number i coil (coil 157) from the first end 150, and the second resistor 155 is connected between the last coil 158 and a number i coil (coil 159) from the second end 151, wherein i≧2. In addition, a resistance of each of the first resistor 154 and the second resistor 155 ranges from 100 ohms to 1000 ohms. In the embodiment, the number i=5, and a resistance of each of the first resistor and the second resistor is 430 ohms.

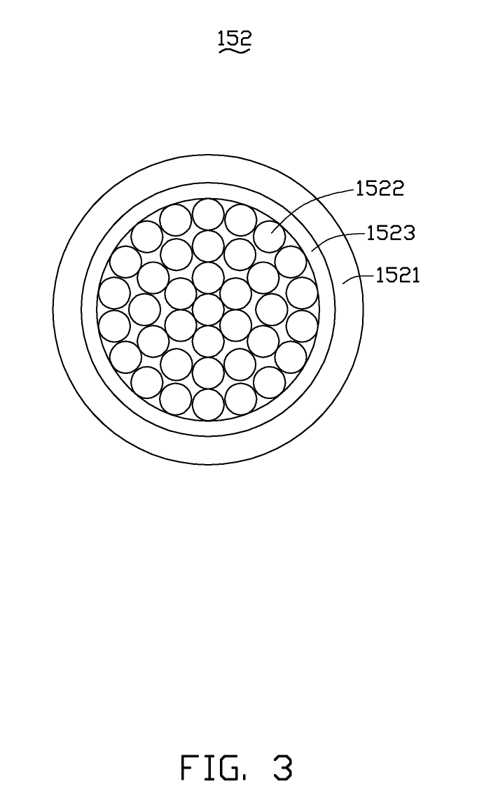

FIG. 3 shows a cross-sectional view of the coil of wire 152 of the first inductor 15 of FIG. 2. The coil of wire 152 includes a number of metal leads 1522, a plastic cover 1521 surrounding the number of metal leads 1522 and a shielding layer 1523 located between the plastic cover 1521 and the metal leads 1523. The metal leads 1522 are copper and electrically contact each other.

Because of the first and the second resistors 154 and 155 connecting two coils of the wire 152, the first inductor 15 can receive a large current, accordingly, the reliability of the LISN 10 is improved. The LISN 10 can test the EMI data generated by the zero line of the power supply or the voltage line of the power supply by using the switch 18.

It is to be further understood that even though numerous characteristics and advantages of preferred and exemplary embodiments have been set out in the foregoing description, together with details of the structures and functions of the embodiments, the disclosure is illustrative only; changes may be made in detail, especially in the matters of shape, size and arrangement of parts within the principles of the present disclosure to the full extent indicated by the broad general meaning of the terms in which the appended claims are expressed.

What is claimed is:

1. A line impedance stabilization network (LISN), comprising:
a power port to connect to a power supply;
an equipment under test (EUT) connection port to connect to an EUT; and
a first inductor connected between the power port and the EUT connection port, the inductor comprising a first end and an opposite second end, a wire connected between the first end and the second end, and a first resistor; and
a switch;
wherein the wire comprises a plurality of coils, and the first resistor connected between two different coils of the wire, the power port comprises a first terminal to connect to a zero line of the power supply, and a second terminal to connect to a voltage line of the power supply, the EUT connection port comprises a first terminal to connect to a zero terminal of the EUT, a second terminal to connect to a voltage terminal of the EUT, and a grounded terminal to connect to a grounded terminal of the EUT, the first inductor is connected between the first terminal of the power port and the first terminal of the EUT connection port, the second inductor is connected between the second terminal of the power port and the second terminal of the EUT connection port, and the grounded terminal of the power port is connected the grounded terminal of the EUT connection port; and the switch is configured to switch between the first output terminal and the second output terminal according to user's selection, thereby making the LISN test EMI data generated by the zero line of the power supply or the voltage line of the power supply.

2. The LISN of claim 1, wherein the plurality of coils define a first coil connected the first end and a last coil connected the second end, the first resistor is connected between the first coil and a number i coil from the first end, and i≧2.

3. The LISN of claim 2, wherein the first inductor further comprises a second resistor, and the second resistor is connected between the last coil and the number i coil from the last end.

4. The LISN of claim 3, wherein i is 5.

5. The LISN of claim 3, wherein a resistance of each of the first resistor and the second resistor ranges from 100 ohms to 1000 ohms.

6. The LISN of claim 3, wherein a resistance of each of the first resistor and the second resistor is 430 ohms.

7. The LISN of claim 1, wherein the first inductor further comprises a coil holder, the wire wraps around the coil holder to form the plurality of coils.

8. The LISN of claim 1, further comprising a first capacitor, a second capacitor, a grounded resistor, and an electromagnetic interference (EMI) output port for connecting an EMI test equipment, wherein the first end is connected the power port, the second end is connected the EUT connection port, the first capacitor is connected between the first end and the ground, an end of the second capacitor is connected the second end, the other end of the second capacitor is grounded via the grounded resistor, and the EMI output port is connected a node between the second capacitor and the grounded resistor.

9. The LISN of claim 1, further comprising a first capacitor, a second capacitor, a third capacitor, a fourth capacitor, a first grounded resistor, and a second grounded resistor, wherein the second inductor comprises a first end connected the second terminal of the power port and a second end connected the second terminal of the EUT connection port, the first end of the first inductor is connected the first terminal of the power port, the second end of the first inductor is connected the first terminal of the EUT connection port, the first capacitor is connected between the first end of the first inductor and the ground, an end of the second capacitor is connected the second end of the first inductor, the other end of the second capacitor is grounded via the first grounded resistor, the third capacitor is connected between the first end of the second inductor and the ground, an end of the fourth capacitor is connected the second end of the second inductor, the other end of the fourth capacitor is grounded via the second grounded resistor.

10. The LISN of claim 9, further comprising an EMI output port for connecting an EMI test equipment, wherein the EMI output port comprises a first output terminal and a second output terminal, the first output terminal is connected a node between the second capacitor and the first grounded resistor, and the second output terminal is connected a node between the fourth capacitor and the second grounded resistor.

11. The LISN of claim 1, wherein the wire comprises a plurality of metal leads and a plastic cover surrounding the plurality of metal leads.

12. The LISN of claim 11, wherein the plurality of metal leads electrically contact each other.

13. The LISN of claim 11, wherein the plurality of metal leads are copper leads.

14. The LISN of claim 11, wherein the wire further comprises a shielding layer located between the plastic cover and the metal leads.
